(19) United States
(12) Patent Application Publication
(10) Pub. No.: US 2011/0086756 A1
(43) Pub. Date: Apr. 14, 2011

(54) METHOD FOR PREPARING SILICON INTERCALATED MONOLAYER GRAPHENE

(76) Inventors: Hong-jun Gao, Beijing (CN); Yi Pan, Beijing (CN); Min Gao, Beijing (CN); Jinhai Mao, Beijing (CN); Li Huang, Beijing (CN); Haitao Zhou, Beijing (CN); Yeliang Wang, Beijing (CN); Haiming Guo, Beijing (CN); Shixuan Du, Beijing (CN)

(21) Appl. No.: 12/973,462

(22) Filed: Dec. 20, 2010

(51) Int. Cl. B01J 37/025; B01J 37/08; B01J 21/18; H01L 21/322; B82Y 40/00

(52) U.S. Cl. 502/182; 117/2; 977/734

(57) ABSTRACT

A method of preparing the electronic material called silicon intercalated epitaxial monolayer graphene comprises the steps of growing large scale high-quality graphene on metal surface, depositing silicon on the prepared epitaxial graphene and annealing to high temperature to intercalate the silicon to the interface of graphene and metal surface. Depending on the quantity of the silicon deposited on the graphene surface, the numbers of the silicon layers on the interface can be controlled and adjusted.

### BACKGROUND OF THE INVENTION

1. Field of the Invention

The present invention relates to a method for preparing the electronic material, silicon intercalated epitaxial monolayer graphene. Specifically, by combining two conventional techniques, large scale high-quality silicon intercalated monolayer graphene was prepared in a controllable way. This approach can have a great potential of application in the future electronic logic devices based on graphene.

2. Description of the Related Art

Since the first piece of monolayer graphene was obtained from highly oriented pyrolytic graphite (HOPG) via mechanical exfoliation method in 2004, it has pushed the upsurge of the investigation on this new two-dimensional materials due to its promising application potential in electronics, information storage materials and catalysis.

Needless to say, for the application in the industry, the large scale high-quality graphene is needed. The method by mechanical exfoliation from graphite can not satisfy this due to the low efficiency. Epitaxial graphene on the metal surface by pyrolyze the hydrocarbon precursor is an impelling candidate for the industry application.

Although it is possible to grow large scale high-quality graphene on metal surface, the graphene is not freestanding like or the electronic properties of graphene are disturbed due to the hybridization of the orbitals of graphene and substrate [Nature materials 7, 406, (2009); Europhys. Lett., 44 (1), 44-49 (1998)]. This is one of the drawbacks of the epitaxial graphene on metal surface. Though intercalation of other metal layer to the interface between graphene and substrate to make the freestanding like graphene, the graphene obtained by this method is still on metal surface, which can not be compatible with traditional silicon devices [Phys. Rev. Lett. 101, 157601 (2008);].

Ways to bridge the gap between large scale graphene growth and compatibility with traditional technique is hence desirable, so that the silicon intercalated to the interface between graphene and metal surface would fit both aspects mentioned above properly.

### SUMMARY OF THE INVENTION

An object of the invention is to overcome at least some of the drawbacks relating to the industrial application of graphene as mentioned above.

Hence, in a first aspect there is provided a method for preparing the electronic material, large scale high-quality silicon intercalated epitaxial monolayer graphene on metal surface. This method comprises the steps of growing large scale high-quality graphene on metal surface, depositing silicon on the prepared epitaxial graphene and annealing to high temperature to intercalate the silicon to the interface of graphene and metal surface. Depending on the quantity of the silicon deposited on the graphene surface, the numbers of the silicon layers on the interface can be controlled.

The growth of large scale high-quality graphene on metal surface may result in cleaning the metal surfaces and exposing the metal surfaces to the hydrocarbon gas precursor at high temperature to get the high-quality epitaxial graphene.

After the preparing of graphene, the silicon is deposited to the graphene surface by the Molecular Beam Epitaxial (MBE) method. The silicon cluster can be monitored to determine the quantity to be intercalated to the interface in the next step. Then the silicon deposited graphene is annealing to high temperature. This process can provide sufficient energy to the silicon atoms to get cross the barrier caused by the continuous graphene to the interface.

The word ‘monitor’ is intended to encompass a general concept of being able to tune the numbers of layers of silicon at the interface between graphene and metal substrate.

In summary, the silicon intercalated graphene on metal surface can be obtained. There is advantage in a number of ways, including the fact that the high-quality graphene successfully epitaxial growth on metal surface. This invention makes transfer technique independent because there is no need to put the graphene on the silicon wafer again.

All these and other introductions of the present invention will become much clear when the drawings as well as the detailed descriptions are taken into consideration.

### BRIEF DESCRIPTION OF THE DRAWINGS

For the full understanding of the nature of the present invention, reference should be made to the following detailed descriptions with the accompanying drawings in which:

FIG. 1 shows the photo of the metal substrate, in our case Ru(0001) surface.

FIG. 2 illustrates the Scanning Tunneling Microscope (STM) image of clean ruthenium substrate after the cleaning process, in our case cycles of sputtering and annealing, showing no impurity on the surface.

FIG. 3 describes the Low Energy Electron Diffraction (LEED) pattern of epitaxial graphene on Ru(0001). The sharp LEED pattern demonstrates the high-quality of the graphene by this method in macroscopy.

FIG. 4 shows the zoom-in step by step STM images of the graphene on Ru(0001). The atomic resolution of the graphene shows the high-quality in microscopy.

FIG. 5 discloses the LEED pattern after the silicon intercalation. The additional spot in the LEED pattern correspond to the ordered silicon on Ru(0001).

FIG. 6 introduces the STM images of the silicon intercalated graphene which is under monolayer coverage.

Like reference numerals refer to like parts throughout the several views of the drawings.

### DESCRIPTION OF THE PREFERRED EMBODIMENT

The present invention will be described more fully hereinafter with reference to the accompanying drawings, in which some examples of the embodiments of the invention are shown. Indeed, the present invention may be embodied in many different forms and should not be construed as limitation to the embodiments set forth herein, rather, these embodiments are provided by way of example so that this disclosure will satisfy applicable legal requirements. Like numbers refer to like elements throughout.

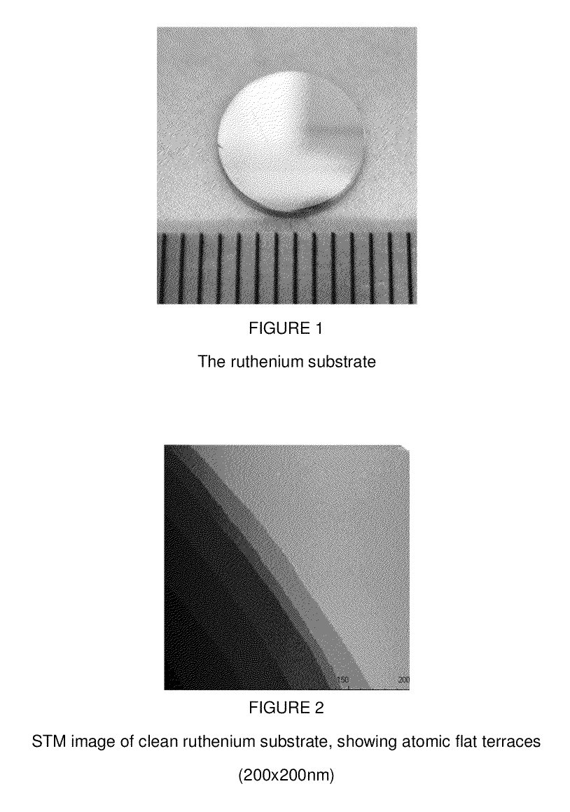

FIG. 1 shows the photo of the metal surface used to grow graphene. In the present example, the aforementioned Ruthenium orientation 0001 (Ru(0001)) substrate is utilized. The choosing of single crystal is just for checking the quality of graphene by the aforementioned STM easier. The same method is also applicable to polycrystalline metal substrate, as set forth above. FIG. 2 describes the aforementioned clean surface of the Ru(0001) surface, as set forth above. The aforementioned clean surface is important to the growth of high-quality graphene. The present experiment was performed in ultrahigh vacuum (UHV), and the aforementioned Ru(0001) is prepared by cycles of Ar⁺ sputtering and annealing to 1000K (Kelvin). The pressure of 5×10⁻⁶ mbar is chosen. After the aforementioned cleaning process, the whole surface remains just the Ru(0001) atoms, which are quite active for the catalysis. After the disposal, the metal surface, as set forth above, is heated to high temperature, at least 1000K, and exposed to the aforementioned hydrocarbon precursor gas, ethylene in the present case. The range of the pressure for the aforementioned ethylene in the present experiment can be from 1×10⁻⁶ mbar to 1×10⁻² mbar. The time for the exposition just depends on the gas pressure used in the experiment, as set forth above. For example, to get monolayer graphene on the aforementioned Ru(0001), we just utilize the parameter as follows:
Pressure: 5×10⁻⁶ mbar
Time: 60s

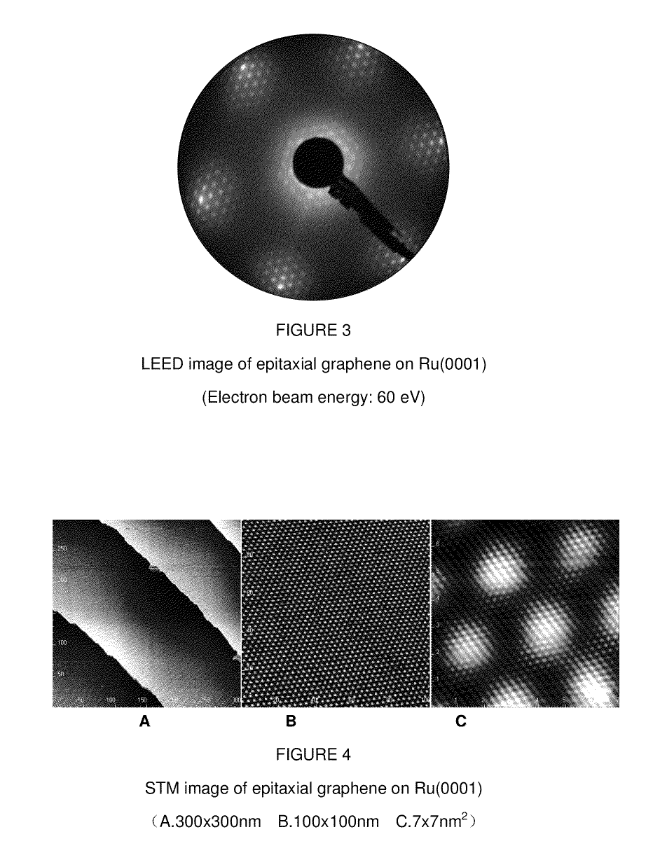

FIG. 3 introduces the LEED pattern of the metal surface after the present process. By elaborating analysis of the LEED pattern, as set forth above, we can ensure that the clean metal has been covered by the graphene films. To certify the quality of the aforementioned epitaxial graphene, LEED patterns, as set forth above, have been taken allover the sample and added together. These results prove that the aforementioned graphene is a single crystal. The aforementioned STM illustrations at different scale in FIG. 4 further prove the high-quality of grapheme, as set forth above. In FIG. 4c, we can clearly identify the atomic structure of the aforementioned graphene and no defect exists.

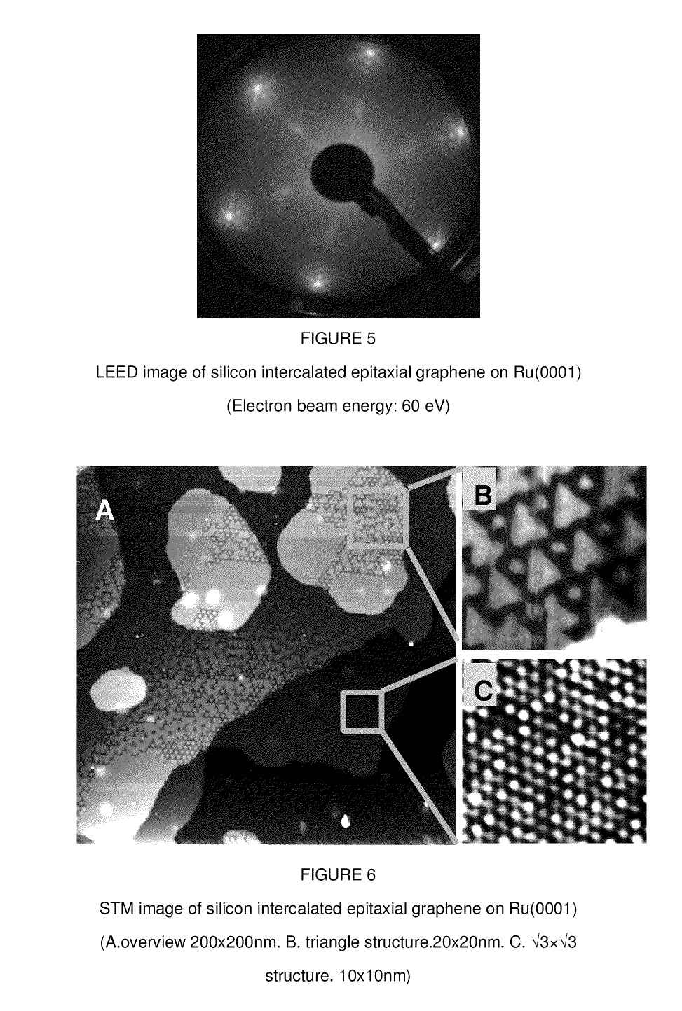

Moving on now to silicon intercalation process, as set forth above, the silicon is evaporated to the aforementioned graphene surface by the aforementioned MBE technique and the quantity can be monitored by the flux of the silicon beam. The present experiment is also performed in vacuum to ensure the purity of the silicon, as set forth above. The aforementioned silicon deposited graphene is then annealed to the high temperature to provide sufficient energy for the aforementioned silicon atoms intercalated to the aforementioned interface. The aforementioned LEED pattern is utilized to monitor and illustrate the successful intercalation process as shown in FIG. 5. FIG. 6 discloses the tune of the size of silicon islands on the interface, as set forth above. FIG. 5B depicts the small triangle structure of the aforementioned silicon island at low coverage. When increasing the aforementioned coverage, the high-ordered and uniform structure can be obvious both in FIG. 5A and FIG. 5C. Further increasing the quantity of the aforementioned silicon, multilayer of silicon can be intercalated to the aforementioned interface, and the distance between the aforementioned graphene and metal substrate can be tuned accordingly.

The method of the present invention is not meant to be limited to the aforementioned experiment, and the subsequent specific description utilization and explanation of certain characteristics previously recited as being characteristics of this experiment are not intended to be limited to such techniques.

Many modifications and other embodiments of the present invention set forth herein will come to mind to one ordinary skilled in the art to which the present invention pertains having the benefit of the teachings presented in the foregoing descriptions. Therefore, it is to be understood that the present invention is not to be limited to the specific examples of the embodiments disclosed and that modifications, variations, changes and other embodiments are intended to be included within the scope of the appended claims. Although specific terms are employed herein, they are used in a generic and descriptive sense only and not for purposes of limitation.

1. A method of preparing an electronic material called silicon intercalated epitaxial monolayer graphene comprises steps of growing large scale high-quality graphene on metal surface, depositing silicon on the prepared epitaxial graphene and annealing to high temperature to intercalate said silicon to an interface of graphene and metal surface wherein numbers of silicon layers on said interface can be controlled depending on the quantity of said silicon deposited on said graphene surface.

2. A method as recited in claim 1, wherein said numbers of said silicon layers correspond to a spatial scale and said spatial scale can be tuned by said quantity of said silicon deposited.

3. A method as recited in claim 1, wherein said numbers of said silicon layers correspond to a spatial distribution of whole sample surface which can be tuned by said quantity of said silicon deposited.

4. A method as recited in claim 1, wherein said step of growing large scale high-quality graphene on metal surface involves cleaning said metal surfaces to the extent at least catalytic activity can be obtained.

5. A method as recited in claim 1, wherein said step of growing large scale high-quality graphene on said metal surface involves providing carbon source, either gas precursor or solid carbon source, wherein said metal surfaces at least containing carbon element.

6. A method as recited in claim 1, wherein said step of growing large scale high-quality graphene on said metal surface involves providing high temperature to substrate cracking said carbon source, either gas precursor or solid carbon source.

7. A method as recited in claim 1, wherein said step of depositing silicon on said graphene surface involves providing an Molecular Beam Epitaxial (MBE) technique in the form of at least heating said silicon to providing silicon clusters to said graphene surfaces.

8. A method as recited in claim 1, wherein said step of annealing said sample involves providing heater to said silicon deposited graphene to provide sufficient energy for silicon intercalation process.

9. A method as recited in claim 1, wherein said silicon layers between said graphene and Ruthenium orientation 0001 (Ru 0001) surface can be oxide by the oxygen due to the activity of said silicon to form a silica and said spatial distribution of said silicon/silica layer can be controlled by the deposition of said silicon and said oxide process.

10. A method as recited in claim 9, wherein said spatial distribution of said silicon layers can be controlled, and areas without silicon/silica can be made into devices separately with different device performance or into device integrated for different part of device.

11. A method as recited in claim 9, wherein said silicon/silica at an interface between said graphene and said metal surface can be used as a buffer layer to introduce a back gate for device design or application.

12. A method as recited in claim 9, wherein numbers of said silicon/silica layer can be tuned, and distance between said graphene and said back gate voltage can be tuned through said metal substrate.

13. A method as recited in claim 12, wherein distance between said graphene and said back gate can be tuned or controlled, and the scattering or screening of said gate voltage can be minimized, wherein the sensitivity of the response of said device to said gate voltage can be maximized.

14. A method as recited in claim 12 wherein said distance between said graphene and said back gate can be tuned, or controlled, and doping of graphene by said gate voltage can be tuned more easily or controllable.

15. A method as recited in claim 9, wherein number of said silicon/silica can be controlled elaborately, and the uniformity of the performance of said devices made by said silicon/silica will largely be enhanced.

16. A method as recited in claim 9, wherein said spatial distribution of said silicon/silica layer can be obtained and the different area with/without said silicon/silica can act as different templates for growth wherein different interfaces with different materials can be intercalated at different area.

17. A method as recited in claim 16, wherein said different interfaces can be obtained by intercalating different materials wherein the properties of said graphene can be tuned, and the areas with said different interfaces or different material intercalation can be made into said devices separately with different device performance or integrated for different part of device.

18. A method as recited in claim 1, wherein said large scale high-quality graphene can be grown and said sample surface can be used as a template to tune the growth of a catalyst cluster wherein the different properties of said graphene surface caused by said interface with/without silicon can also be used as said template to tune the growth of said catalyst cluster.

19. A method as recited in claim 18, wherein said catalyst cluster can be grown, the size of said cluster can be tuned by the quantity of deposition and the catalytic activity of said catalyst cluster can be tuned wherein said different catalyst clusters can be grown on the same surface.

20. A method as recited in claim 18, wherein the area with/without said silicon intercalated graphene can be used as said template to tune the growth of said catalyst clusters and said spatial distribution of said catalyst can be tuned by controlling the size of said silicon/silica island at said interface, and said different catalyst will self-organize at said different areas.
